(19) United States
(12) Patent Application Publication
(10) Pub. No.: US 2026/0003299 A1
(43) Pub. Date: Jan. 1, 2026

(54) SUBSTRATE STRUCTURE

(71) Applicant: Samsung Electronics Co., Ltd., Suwon-si (KR)

(72) Inventors: Sungmoon PARK, Suwon-si (KR); Byounghoon KIM, Suwon-si (KR); Sung Woon UH, Suwon-si (KR); Eunhee JEANG, Suwon-si (KR); Dong-Wook KIM, Suwon-si (KR); Doo-Ho PARK, Suwon-si (KR); Sungmo YANG, Suwon-si (KR); Junho YOON, Suwon-si (KR)

(73) Assignee: Samsung Electronics Co., Ltd., Suwon-si (KR)

(21) Appl. No.: 18/968,226

(22) Filed: Dec. 4, 2024

(30) Foreign Application Priority Data
Jul. 1, 2024 (KR) 10-2024-0086030

(51) Int. Cl. G03F 9/00

(52) U.S. Cl. CPC G03F 9/7088; G03F 9/7076

(57) ABSTRACT

A substrate structure including a substrate, and an alignment mark on the substrate and configured to align an alignment of the substrate may be provided. The alignment mark may include a first main pattern in which a first main segment extending in a first direction repeats in a second direction perpendicular to the first direction, and a second main pattern in which a second main segment extending in the second direction repeats in the first direction. When viewed in a plan view, the first main pattern and the second main pattern ma define a quadrangle pattern, and the first main pattern and the second main pattern may be configured to diffract a light incident on the alignment mark.

### CROSS-REFERENCE TO RELATED APPLICATION

This application claims priority to Korean Patent Application No. 10-2024-0086030, filed in the Korean Intellectual Property Office on Jul. 1, 2024, the entire contents of which are hereby incorporated by reference.

### BACKGROUND

### Field

The present disclosure relates to substrate structures including an alignment mark.

### Description of Related Art

An exposure process for forming a circuit pattern on a wafer substrate may be performed during semiconductor manufacturing. Before performing the exposure process, it is essential to align the wafer substrate, for which an alignment mark may be used. For an accurate exposure process, a scanner that scans the alignment mark using Deep UV (DUV) or Extreme UV (EUV) may be used.

A technique for calculating the position of the alignment mark through intensity and relative phase difference generated by overlapping diffraction beams diffracted from the alignment mark may be used during scanning. In order to align the wafer substrate more precisely, the number, size, design, etc. of alignment marks are being studied.

### SUMMARY

In order to solve one or more problems (e.g., the problems described above and/or other problems not explicitly described herein), the present disclosure provides substrate structures with reduced error occurrence during position alignment.

In order to solve one or more problems (e.g., the problems described above and/or other problems not explicitly described herein), the present disclosure provides alignment marks with improved alignment performance by improving optical performance and reducing the influence by the process.

According to some example embodiments of the present disclosure, a substrate structure may include a substrate, and an alignment mark on the substrate and configured to align the substrate, wherein the alignment mark may include a first main pattern in which a first main segment extending in a first direction repeats in a second direction perpendicular to the first direction, and a second main pattern in which a second main segment extending in the second direction repeats in the first direction, wherein the first main pattern and the second main pattern define quadrangle pattern in a plan view, and the first main pattern and the second main pattern are configured to diffract a light incident on the alignment mark.

According to some example embodiments of the present disclosure, a substrate structure may include a substrate including a chip area and a scribe lane surrounding the chip area, and an alignment mark on the scribe lane and configured to diffract incident light, wherein the alignment mark includes a first main pattern in which a first main segment extending in a first direction repeats in a second direction perpendicular to the first direction, a second main pattern in which a second main segment extending in the second direction repeats in the first direction, a first sub-pattern including a first sub-segment, the first sub-segment repeating along the first direction on the first main segment, a second sub-pattern including a second sub-segment, the second sub-segment repeating along the second direction on the second main segment, a length of the first main segment in the first direction increases from a center of the alignment mark toward an edge of the alignment mark, and a length of the second main segment in the second direction increases from the center of the alignment mark toward the edge of the alignment mark.

According to some example embodiments of the present disclosure, a substrate structure may include a substrate and an alignment mark on the substrate, wherein the alignment mark includes a base, a first main pattern in which a first main segment protruding from the base and extending in a first direction repeats in a second direction perpendicular to the first direction, a second main pattern in which a second main segment protruding from the base and extending in the second direction repeats in the first direction, a first sub-pattern including a first sub-segment, the first sub-segment repeating along the first direction on the first main segment, a second sub-pattern including a second sub-segment, the second sub-segment repeating along the second direction on the second main segment, a first separation groove extending in the second direction and configured to separate the first main pattern in the first direction, and a second separation groove extending in the first direction and configured to separate the second main pattern in the second direction, wherein a length of the first main segment in the first direction increases from a center of the alignment mark toward an edge of the alignment mark, a length of the second main segment in the second direction increases from the center of the alignment mark toward the edge of the alignment mark, and wherein when viewed in a plan view, the first main pattern and the second main pattern define a quadrangle pattern having a same center as the center of the alignment mark.

According to some example embodiments of the present disclosure, errors occurrence during position alignment of the substrate structure can be reduced.

According to some example embodiments of the present disclosure, the alignment mark can have improved optical performance and/or reduced process-related influences, thereby improving alignment performance.

### BRIEF DESCRIPTION OF THE DRAWINGS

FIG. 1 is a diagram schematically illustrating a lithographic apparatus.

FIG. 2 is a diagram schematically illustrating a structure of the optical module of FIG. 1.

FIG. 3 is a diagram illustrating a substrate structure according to an example embodiment.

FIG. 4 is a diagram provided to explain the shot area of FIG. 3.

FIG. 5 is a diagram illustrating an alignment mark according to an example embodiment.

FIG. 6 is an enlarged view of a portion of the alignment mark of FIG. 5.

FIG. 7 is a diagram illustrating a portion of an alignment mark according to an example embodiment.

FIG. 8 is a diagram illustrating a portion of an alignment mark according to an example embodiment.

FIGS. 9 and 10 are diagrams provided to explain a method of aligning a substrate structure using a diffraction beam technology.

FIG. 11 is a graph illustrating a signal acquired from diffraction beam sensed by the optical module of FIG. 2.

FIGS. 12 to 19 are diagrams illustrating alignment marks according to some example embodiments.

### DETAILED DESCRIPTION

A substrate structure according to some example embodiments of the present disclosure will be described in detail with reference to the drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

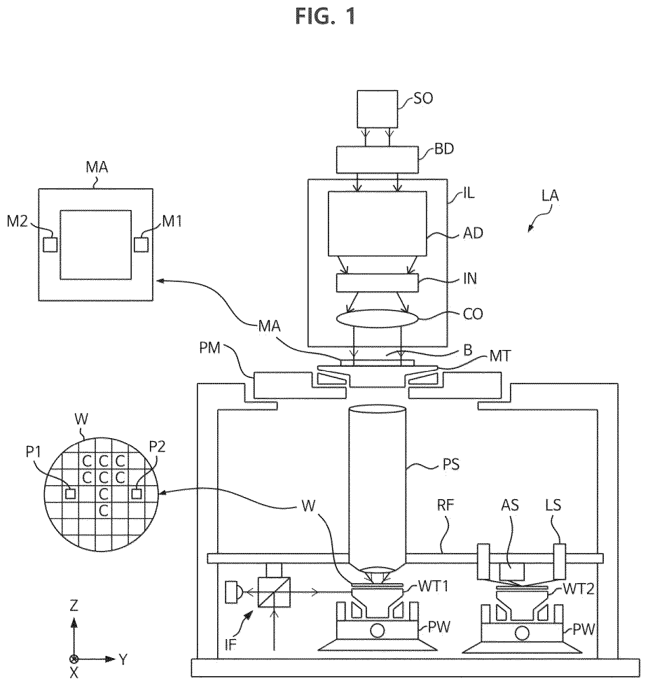

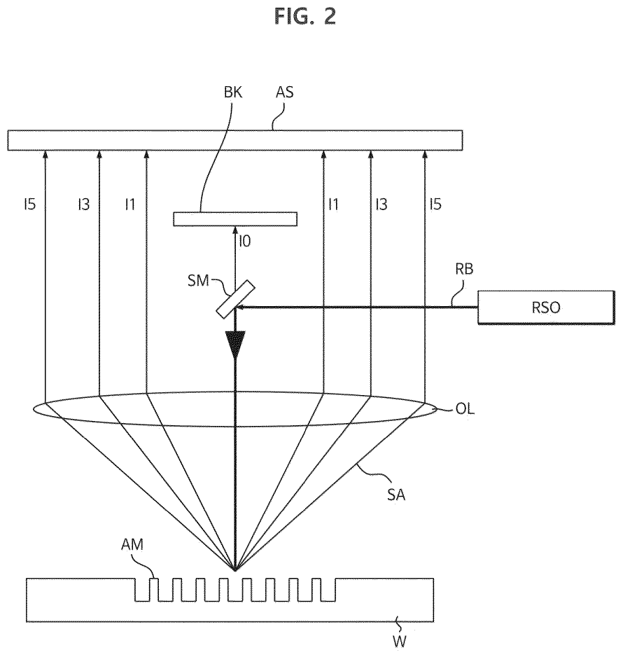

FIG. 1 is a diagram schematically illustrating a lithographic apparatus. FIG. 2 is a diagram schematically illustrating a structure of the optical module of FIG. 1.

Referring to FIG. 1, the lithographic apparatus LA may include a source SO, an illuminator IL, a patterning device MA, a first positioner PM, a mask table MT, a second positioner PW, wafer tables WT1 and WT2, and a projection system PS.

Hereinafter, two directions substantially parallel to an upper surface of a wafer W disposed inside the lithographic apparatus LA and substantially perpendicular to each other may be defined as first and second directions (X and Y directions). In addition, a direction substantially perpendicular to the upper surface of the wafer may be defined as a third direction (Z direction).

For example, the source SO may emit a radiation beam B such as ultraviolet rays, an excimer laser beam, EUV light (extreme ultraviolet rays), X rays, electron rays, etc. In some cases, the source SO may be some of components of the lithographic apparatus LA or a separate component. If the source is an excimer laser, the source SO may be a separate configuration from the lithographic apparatus LA. In this case, the radiation beam B may be transferred from the source SO to the illuminator IL by a beam transfer system BD including a beam expander. If the source SO is a mercury lamp, the source SO may be included in the lithographic apparatus LA. The terms “radiation” and “beam” as used herein may encompass all types of electromagnetic radiation, including ultraviolet (UV) (e.g., having a wavelength of about 365, 355, 248, 193, 157 or 126 nm) and extreme ultraviolet (EUV) (e.g., having a wavelength in the range of 1 to 100 nm), as well as particle beams such as ion beams or electron beams.

The illuminator IL may receive the radiation beam B from the source SO. The illuminator IL may direct the direction of the radiation beam B in a set direction, or shape or control the shape of the radiation beam B. According to some example embodiments, the illuminator IL may include various types of optical components, including a refractive type, a reflective type, a magnetic type, an electromagnetic type, an electrostatic type, or a combination thereof.

The illuminator IL may include a regulator AD, an integrator IN, and a condenser CO, which are configured to adjust the intensity distribution according to the angle of the radiation beam B. The regulator AD may adjust an outer radius and/or inner radius size, etc. of the intensity distribution of the pupil plane of the illuminator IL. The illuminator IL may adjust the radiation beam B such that the cross section of the radiation beam B has a desired uniformity and intensity distribution. The illuminator IL may adjust the radiation beam so as to have the desired uniformity and intensity distribution in the cross section of the radiation beam.

The mask table MT may support the patterning device MA. The mask table MT may use mechanical, vacuum, electrostatic, or any of various clamping techniques to hold the patterning device MA. According to some example embodiments, the mask table MT may be a fixed frame or table. According to some other example embodiments, the mask table MT may be a movable frame or table. The mask table MT may position the patterning device MA at a position set for the projection system PS. The radiation beam B may be incident on the patterning device MA supported by the mask table MT. The cross section of the radiation beam B incident on the patterning device MA may be changed to a shape set by the patterning device MA. The projection system PS may include a refractive type, a reflective type, a catadioptric type, a magnetic type, an electromagnetic type and an electrostatic optical type, and a combination of at least some of these.

According to some example embodiments, the patterning device MA may be transmissive or reflective. For example, the patterning device MA may be any one of a mask, a programmable mirror array, or programmable LCD panels. If the patterning device MA is a mask type, the patterning device MA may be any one of a binary type, an alternating phase-shift type, a damping phase-shift type, or a variety of hybrid types, but is not limited thereto.

If the patterning device MA is a programmable mirror array, the patterning device MA may include a set of small mirrors arranged in the form of a matrix, for example. Each of the small mirrors included in the patterning device MA may be individually inclined to reflect radiation beams incident on the small mirrors in different directions. Each of the inclined small mirrors may form a pattern on the radiation beam B reflected by the mirror matrix. The radiation beam B may pass through the projection system PS. The projection system PS may focus the radiation beam B on a target portion C of the wafer W. According to some example embodiments, the second positioner PW and a position sensor IF may drive the wafer table WT1 such that the radiation beam B is sequentially focused on the target portion C of the wafer W disposed on the wafer table WT1.

In the lithographic apparatus LA, two wafer tables WT1 and WT2 may be exchanged. While the wafer W on one wafer table WT1 is being exposed, the other wafer may be loaded on the other wafer table WT2 and wafer alignment, etc. may be performed.

The second positioner PW may drive the wafer tables WT1 and WT2 to implement the designed circuit pattern. According to some example embodiments, the second positioner PW may drive the wafer tables WT1 and WT2 such that the radiation beam is focused at a set position on the wafer W. The set position on the wafer W may be defined from a model function calculated using wafer alignment marks P1 and P2. The model function refers to a function of positions identified by the wafer alignment marks P1 and P2, or a function of the identified position of any component on the wafer from the identified positions. The second positioner PW may drive the wafer table WT1 such that a layer formed on the wafer W is aligned with an underlying layer by a lithography process to form a normally operating semiconductor device.

A reference frame RF may be connected to various components and serve as a reference for setting and measuring positions of the features on the patterning device MA and the wafer W. If the position sensor IF fails to measure the positions of the wafer tables WT1 and WT2, the positions of the wafer tables WT1 and WT2 may be calculated based on the reference frame RF.

According to some example embodiments, a space defined between the projection system PS and the wafer W may be filled with a liquid having a high refractive index. In some cases, at least a portion of the wafer W may be covered by the liquid. The liquid is herein referred to as an immersion liquid, and the immersion liquid may fill other spaces within the lithographic apparatus, for example a space defined between the patterning device MA and the projection system PS. In this case, immersion may not only refer to the wafer W being simply immersed in the liquid, but also to the immersion liquid being placed on a path of the radiation beam (B) for performing exposure.

The patterning device MA selected from the mask library may be accurately moved by the first positioner PM and an additional position sensor to be positioned on the path of the radiation beam B during the exposure process.

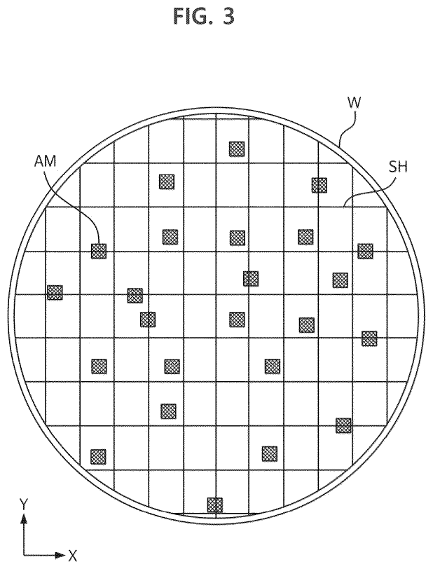

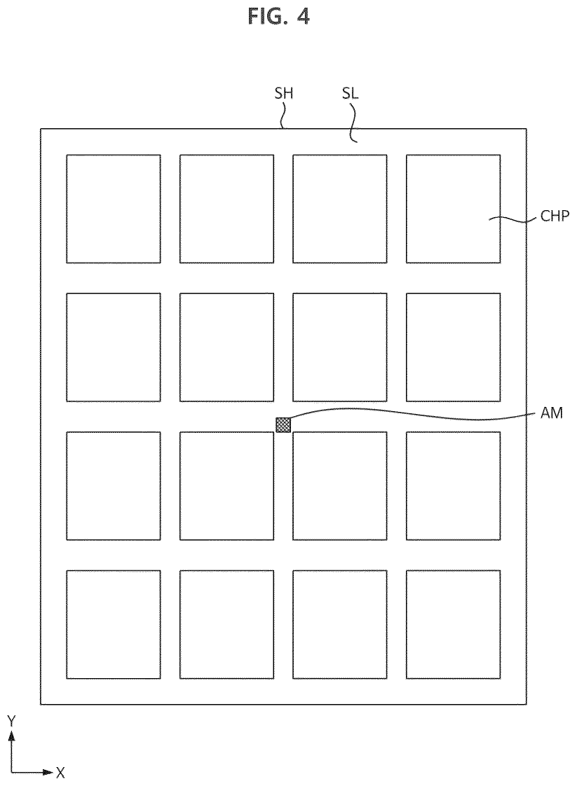

If the lithographic apparatus LA operates in a stepper mode, the entire pattern set in the radiation beam B may be projected on the target portion C at once, while the mask table MT and the wafer table WT1 are maintained in a stopped state. The patterning device MA and the wafer W may be aligned using mask alignment marks M1 and M2 formed on the patterning device MA and the substrate alignment marks P1 and P2 formed on the wafer W. The target unit C may be a full shot or a partial shot which will be described below with reference to FIGS. 3 and 4. The wafer table WT1 may move in a horizontal direction with respect to the upper surface of the wafer W such that another target portion C is exposed. In the stepper mode, the maximum size of the exposure field may define the size of the target portion C imaged during exposure.

If the lithographic apparatus LA operates in a scan mode, the mask table MT and the wafer table WT1 may be synchronized and relatively move while the radiation beam B is projected on the target portion C. The speed and direction of the relative motion of the wafer table WT1 with respect to the mask table MT may be determined by the enlargement (or reduction) and image inversion characteristics of the projection system PS. In the scan mode, the maximum size of the exposure field may limit the horizontal width of the target portion C during exposure.

Referring to FIG. 2, the lithographic apparatus LA may include a scanner for aligning the wafer W placed on the wafer table WT2. The scanner may include an alignment sensor AS that detects light diffracted from the alignment mark AM for alignment in the first direction X and/or the second direction Y. In addition, the scanner may include a level sensor LS for alignment in the third direction Z.

A radiation source RSO may provide a radiation beam RB of one or more wavelengths. The radiation beam RB may be focused on the alignment mark AM positioned on the wafer W by diverting optics. The diverting optics may include a spot mirror SM and an objective lens OL.

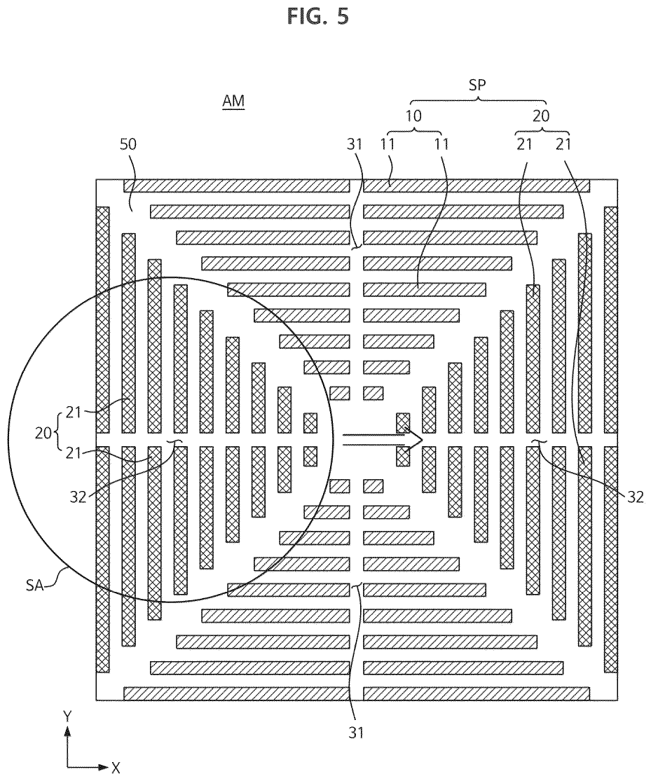

A scan area SA (see FIG. 5) may be formed on the alignment mark AM. The scan area SA may have a size smaller than that of the alignment mark AM. The light focused on the alignment mark AM may be diffracted by a slit structure. The radiation beam diffracted by the alignment mark AM may be collimated into a parallel beam through the objective lens OL. For example, the diffraction beams may include a zero-order diffraction beam (or reflected light) I0, a first-order diffraction beam I1, a third-order diffraction beam I3, a fifth-order diffraction beam I5, etc. Each diffraction beam may be collimated in parallel through the objective lens OL.

The diverting optics may include a blocking unit BK that blocks the zero-order diffraction beam I0 reflected from the alignment mark AM. The collimated diffraction beams may include only higher order diffraction beams I1, I3, and I5 from the alignment mark AM. The alignment sensor AS may measure the intensity of the first-order diffraction beam I1 of the diffraction beams. When the radiation beam RB emitted by the alignment sensor AS interacts with and diffracts from the alignment mark AM, the diffraction beam may include information on the structure of the alignment mark AM, such as a layout, a pitch, etc. In addition, Aligned Position Deviation (APD), which is the difference between the measured position of the alignment mark AM measured by the alignment sensor AS and the actual position of the alignment mark AM, may be calculated.

Hereinafter, the structure of the wafer W and the alignment mark AM disposed on the wafer W will be described.

FIG. 3 is a diagram illustrating a substrate structure according to an example embodiment. FIG. 4 is a diagram provided to explain the shot area of FIG. 3.

Referring to FIGS. 3 and 4, the substrate structure according to an example embodiment may include a substrate. In some example embodiments, the substrate may be a wafer W. However, example embodiments are not limited thereto, and the substrate may be a semiconductor substrate, a glass substrate, etc. instead of the wafer W. The substrate structure is not limited to the semiconductor field. In some example embodiments, the substrate structure may include a substrate of other fields such as a display substrate, etc.

The wafer W may include a plurality of shot areas SH. The shot area SH may be an area exposed by a single exposure process. The shot area SH may include one chip CHP or a plurality of chips CHP. For example, the chip CHP may form a memory device. The chip CHP may form a non-volatile memory device. For example, the chip CHP may form any one of a non-volatile NAND-type flash memory, PRAM, MRAM, ReRAM, FRAM, or NOR flash memory. In addition, the chip CHP may form a volatile memory device such as DRAM and SRAM that loses data when power is cut off. In another example embodiments, the chip CHP may be any one of a logic chip, a measurement element, a communication element, a digital signal processor (DSP), or a System-on-Chip (SOC).

A scribe lane SL may be disposed between a plurality of chips CHP. The scribe lane SL may define an area in which the chip CHP is formed. The scribe lane SL may extend between the chips CHP to separate the chips CHP from each other. The scribe lane SL may be an area for separating the chips CHP from each other in a sawing process.

At least one of the shot areas SH may include an alignment mark AM. The alignment mark AM may be disposed on the scribe lane SL. In some example embodiments, the alignment mark AM may span two adjacent shot areas SH. For example, the alignment mark AM may be disposed adjacent to the central portion of the shot area SH, but example embodiments are not limited thereto.

The alignment mark AM may be a pattern used to accurately set the exposure area in a lithographic process. The alignment mark AM may include several portions. For example, the alignment mark AM may be formed of portions that are disposed on different layers.

The alignment mark AM may be disposed between the chips CHP, of a plurality of chips CHP, that are adjacent to each other in the second direction Y. The alignment mark AM may be disposed between the chips CHP, of the plurality of chips CHP, that are adjacent to each other in the first direction X. For example, the alignment mark AM may have a square shape. However, example embodiments are not limited thereto, and the alignment mark AM may have various shapes.

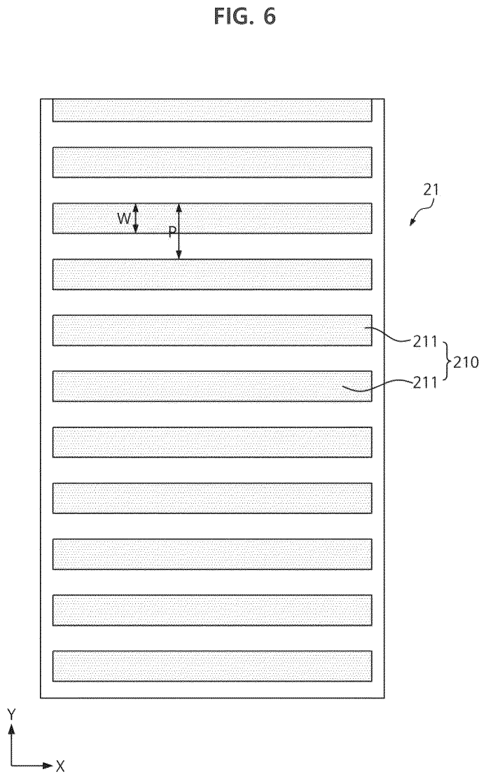

FIG. 5 is a diagram illustrating an alignment mark according to an example embodiment. FIG. 6 is an enlarged view of a portion of the alignment mark of FIG. 5.

Referring to FIGS. 5 and 6, the substrate structure according to an example embodiment may include an alignment mark AM. The alignment mark AM may be disposed on the substrate. The alignment mark AM may include a base 50, a first main pattern 10 formed on the base 50, and a second main pattern 20 formed on the base 50.

The base 50 may form a lower surface of the alignment mark AM. The base 50 may have a square shape. However, example embodiments are not limited thereto, and the base 50 may have various shapes including a rectangular shape, etc. For example, each side of the base 50 may have a length of 40 μm.

The first main pattern 10 may be formed by protruding from the base 50. The first main pattern 10 may include a first main segment 11 protruding from the base 50. The first main segment 11 may extend in the first direction X. The first main segment 11 may be repeated in the second direction Y. For example, the first main segment 11 may be repeated and spaced apart by a desired (or alternatively, predetermined) pitch in the second direction Y. When viewed in a plan view, a portion of the base 50 may be positioned between the first main segments 11. The first main pattern 10 may be formed by repeating the first main segment 11. However, example embodiments are not limited thereto, and the first main segment 11 and the first main pattern 10 may be formed by depressing a portion of the base 50.

The length of the first main segment 11 extending in the first direction X may increase from the center of the alignment mark AM toward the edge of the alignment mark AM along the second direction Y. In other words, the length of the first main segment 11 in the first direction X may be shorter, the closer the first main segment 11 is to the center of the alignment mark AM, and may be longer, the farther the first main segment 11 is from the center of the alignment mark AM.

The second main pattern 20 may be formed by protruding from the base 50. The second main pattern 20 may include a second main segment 21 protruding from the base 50. The second main segment 21 may extend in the second direction Y. The second main segment 21 may be repeated in the first direction X. Specifically, the second main segment 21 may be repeated and spaced apart by a desired (or alternatively, predetermined) pitch in the first direction X. When viewed in a plan view, a portion of the base 50 may be positioned between the second main segments 21. The second main pattern 20 may be formed by repeating the second main segment 21. However, aspects are not limited thereto, and the second main segment 21 and the second main pattern 20 may be formed by depressing a portion of the base 50.

The length of the second main segment 21 extending in the second direction Y may increase from the center of the alignment mark AM toward the edge of the alignment mark AM along the first direction X. In other words, the length of the second main segment 21 in the second direction Y may be shorter, the closer the second main segment 21 is to the center of the alignment mark AM, and may be longer, is the farther the second main segment 21 is from the center of the alignment mark AM.

The first main pattern 10 and the second main pattern 20 may be partitioned from each other based on a diagonal line of the alignment mark AM. For example, among the quadrants partitioned by the diagonal of the alignment mark AM, the first main segment 11 may be positioned on two quadrants facing each other in the second direction Y. Among quadrants partitioned by the diagonal of the alignment mark AM, the second main segment 21 may be positioned on two quadrants facing each other in the first direction X. In addition, the first main pattern 10 and the second main pattern 20 positioned on each quadrant may have the same shape.

As described above, the first main pattern 10 and the second main pattern 20 may have a line-and-space structure. The first main pattern 10 may extend in the first direction X, and the second main pattern 20 may extend in the second direction Y. The first main pattern 10 and the second main pattern 20 may have an optical grating structure.

Light incident on the alignment mark AM may be diffracted by the grating structure of the first main pattern 10 and the second main pattern 20. Light incident on the alignment mark AM may be diffracted by the first main pattern 10 and the second main pattern 20.

When viewed in a plan view, the first main pattern 10 and the second main pattern 20 may form a quadrangle pattern. The alignment mark AM may include a square pattern SP formed by the first main pattern 10 and the second main pattern 20. If the first main segment 11 further extends in the first direction X and the second main segment 12 further extends in the second direction Y, the square pattern SP may be a part of a square formed by the first main segment 11 and a second main segment 12 that are orthogonal to each other. That is, the square pattern SP may not actually form a square, but may be a part of a square formed by the first main segment 11 and the second main segment 12.

The square pattern SP may be formed by the first main segment 11 and the second main segment 12 that are positioned at the same distance from the center of the alignment mark AM. Because each of the length of the first main pattern 10 and the length of the second main pattern 20 is formed to be shorter, the closer each of the first main pattern 10 and the second main pattern 20 is to the center of the alignment mark AM, and longer, the farther each of the first main pattern 10 and the second main pattern 20 is from the center of the alignment mark AM, the size of the square pattern SP may be smaller, the closer each of the first main pattern 10 and the second main pattern 20 is to the center of the alignment mark AM, and may be larger, the farther each of the first main pattern 10 and the second main pattern 20 is from the center of the alignment mark AM.

The center of the square pattern SP may be the same as the center of the alignment mark AM. The square pattern SP may have a concentric square structure that shares the center of the alignment mark AM. For example, each square forming the square pattern SP may share the center of the alignment mark AM. The center of the square may be an intersection point of diagonal lines of the square.

The alignment mark AM may include a first separation groove 31 for separating the first main patterns 10 in the first direction X and a second separation groove 32 for separating the second main patterns 20 in the second direction Y. The first separation groove 31 may extend in the second direction Y, and the second separation groove 32 may extend in the first direction X.

The first separation groove 31 and the second separation groove 32 may separate the first main patterns 10 and the second main patterns 20, respectively, such that foreign substances remaining between the first main patterns 10 and the second main patterns 20 are discharged. The first separation groove 31 may discharge gas or particles remaining between the first main patterns 10. The second separation groove 32 may discharge gas or particles remaining between the second main patterns 20. For example, foreign substances remaining in the first main patterns 10 may be discharged along an extension direction of the first main segment 11, that is, along the first direction X. Because the extension length of the first main segment 11 in the first direction X increases toward the edge of the alignment mark AM, it may be difficult for remaining foreign substances to be discharged. Therefore, the first separation groove 31 separates the first main segments 11 forming the first main pattern 10 in the first direction X, so that foreign substances may be easily discharged. The description of the first separation groove 31 may be equally applied to the second separation groove 32.

The scan area SA may move in the first direction X on the alignment mark AM. The scan area SA may be an area where the light is incident on the alignment mark AM. Diffraction of light may occur in the alignment mark AM by the first main pattern 10 and the second main pattern 20. FIG. 5 illustrates only a scanning operation along the first direction X, but example embodiments are not limited thereto. The operation of scanning along the second direction Y may also be performed. The scanning operation along the first direction X and the scanning operation along the second direction Y may be sequentially performed or may be performed separately. Further, the scanning operation along the second direction Y may be performed first, followed by the scanning operation along the first direction X.

Referring to FIG. 6, a second sub-pattern 210 repeatedly formed along the second direction Y on the second main segment 21 may be included. The second sub-pattern 210 may include a second sub-segment 211 extending along the first direction X. The second sub-segment 211 may have a desired (or alternatively, predetermined) length along the first direction X. The second sub-segment 211 may be formed by protruding or recessed from the second main segment 21.

The extending direction of the second sub-pattern 210 may be changed. In some example embodiments, the second sub-pattern 210 may be repeatedly formed along the first direction X. That is, the second sub-segment may extend along the second direction Y. The second sub-pattern 210 may extend along the second direction Y, and may be repeatedly formed and spaced apart by a desired (or alternatively, predetermined) pitch along the first direction X.

The second sub-pattern 210 may have a width W of the second sub-segment 211 in the second direction Y and a pitch P of the second sub-segment 211 in the second direction Y. The width W and the pitch P of the second sub-segment 211 may affect the intensity, contrast, Alignment Position Deviation (APD), etc. of the refracted light. The width W and the pitch P of the second sub-segment 211 may be selected as appropriate values through experiments under various conditions.

Although the second sub-pattern 210 formed on the second main segment 21 is illustrated, the first sub-pattern may also be formed on the first main segment 11. The description of the second sub-pattern may be equally applied to the first sub-pattern.

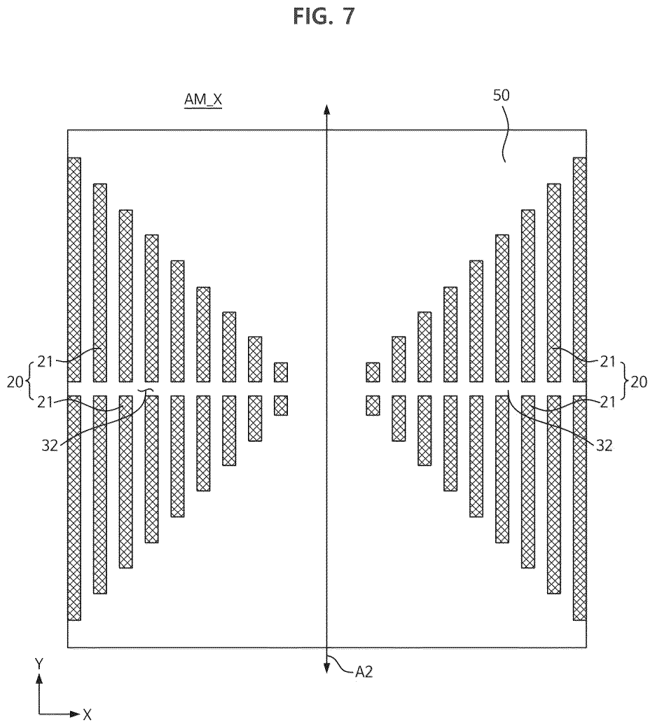

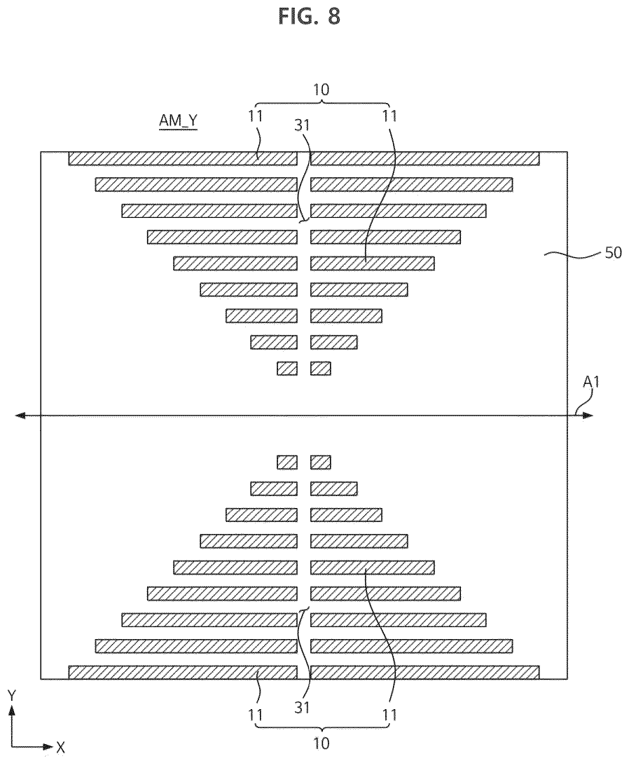

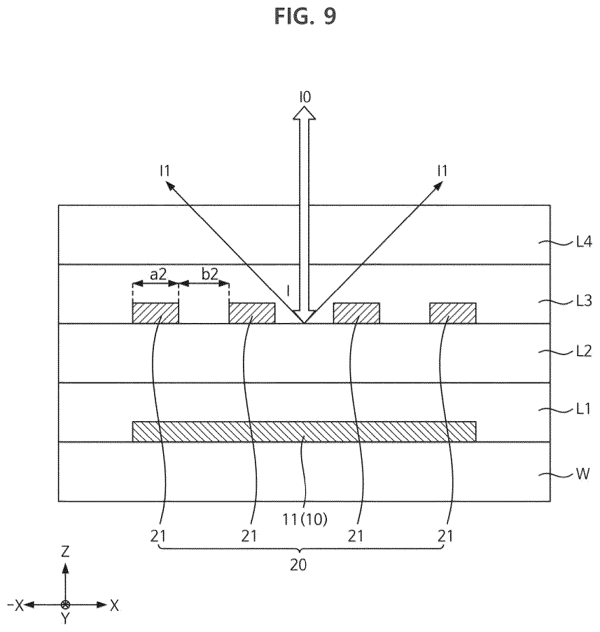

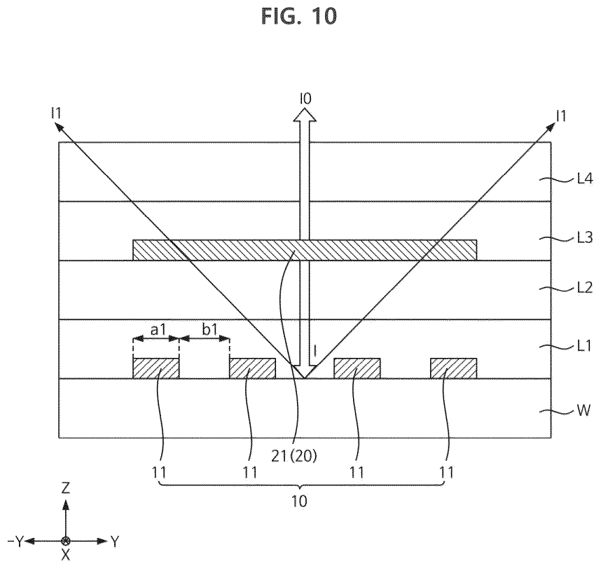

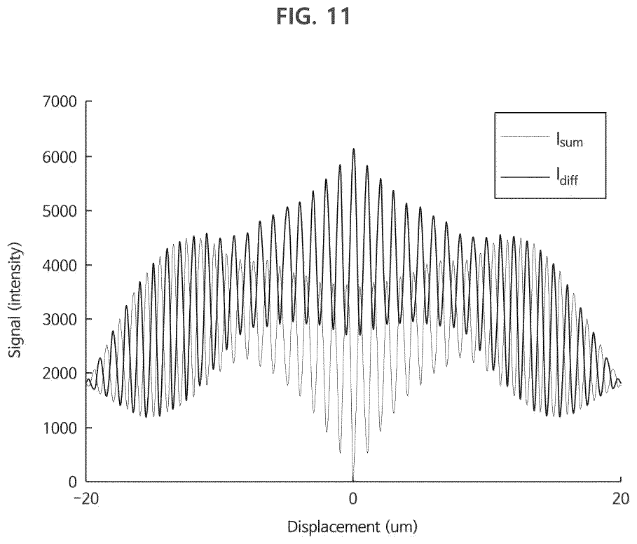

FIG. 7 is a diagram illustrating a portion of an alignment mark according to an example embodiment. FIG. 8 is a diagram illustrating a portion of an alignment mark according to an example embodiment. FIGS. 9 and 10 are diagrams provided to explain a method of aligning a substrate structure using a diffraction beam. FIG. 11 is a graph illustrating a signal acquired from diffraction beam sensed by the optical module of FIG. 2.

Referring to FIGS. 7 and 8, the substrate structure according to some example embodiments may include a first alignment mark AM_Y including the first main pattern 10 and a second alignment mark AM_X including the second main pattern 20. That is, the first main pattern 10 and the second main pattern 20 may be formed on the alignment marks AM_X and AM_Y, which are different from each other, respectively. The first main pattern 10 may extend along the first direction X on the first alignment mark AM_Y and may be formed symmetrically with respect to a symmetry axis A1 passing through the center of the first alignment mark AM_Y. The second main pattern 20 may extend along the second direction Y on the second alignment mark AM_X and may be formed symmetrically with respect to a symmetry axis A2 passing through the center of the second alignment mark AM_X.

Referring to FIGS. 7 to 10, the substrate structure may include a wafer W, a first layer L1, a second layer L2, a third layer L3, and a fourth layer L4. The first layer L1, the second layer L2, the third layer L3, and the fourth layer L4 may be disposed on the wafer W. The second layer L2 may be positioned at a higher level than the first layer L1. The second layer L2 may be stacked on the first layer L1 along the third direction Z. The third layer L3 may be positioned at a higher level than the second layer L2. The third layer L3 may be stacked on the second layer L2 along the third direction Z. The fourth layer L4 may be positioned at a higher level than the third layer L3. Although the fourth layer L4 is illustrated as a single layer, the fourth layer L4 may include a plurality of layers.

The first layer L1, the second layer L2, the third layer L3, and the fourth layer L4 may be optically distinguishable from each other. For example, the first layer L1, the second layer L2, the third layer L3, and the fourth layer L4 may be a conductive layer or an insulating layer. The first layer L1, the second layer L2, the third layer L3, and the fourth layer L4 may be insulating layers having different refractive indices or conductive layers having different reflectivities. According to some example embodiments, the first layer L1, the second layer L2, the third layer L3, and the fourth layer L4 may have a single layer structure or a multilayer structure including a plurality of layers.

The first alignment mark AM_Y may be disposed on the first layer L1, and the second alignment mark AM_X may be disposed on the third layer L3. That is, the first main pattern 10 may be disposed on the first layer L1, and the second main pattern 20 may be disposed on the third layer L3. However, example embodiments are not limited thereto, and the first main pattern 10 may be disposed on the third layer L3, and the second main pattern 20 may be disposed on the first layer L1.

In addition, it is illustrated that only one layer is disposed between the first alignment mark AM_Y and the second alignment mark AM_X, but example embodiments are not limited thereto. For example, two or more layers may be disposed between the first alignment mark AM_Y and the second alignment mark AM_X.

The first alignment mark AM_Y and the second alignment mark AM_X may overlap each other with respect to the third direction Z. On the other hand, the first main pattern 10 and the second main pattern 20 may not overlap each other with respect to the third direction Z. The first main pattern 10 and the second main pattern 20 may not overlap each other in the thickness direction of the wafer W. When viewed in a plan view, the first alignment mark AM_Y and the second alignment mark AM_X may form the same pattern as the alignment mark AM of FIG. 5. That is, when viewed in a plan view, the first main pattern 10 of the first alignment mark AM_Y and the second main pattern 20 of the second alignment mark AM_X may form a quadrangle pattern. For example, the first main pattern 10 and the second main pattern 20 may form a square pattern SP.

A method for calculating an overlay using a diffraction beam will be described with reference to FIGS. 9 and 10. FIG. 9 illustrates diffraction beam when the alignment mark AM_X is scanned along the first direction X, and FIG. 10 illustrates diffraction beam when the alignment mark AM_Y is scanned along the second direction Y.

Referring to FIG. 9, the alignment marks AM_X and AM_Y may be scanned along the first direction X. If light moves along the first direction X, diffraction may occur in the second main pattern 20 extending in the second direction Y perpendicular to the first direction X. Light is incident on the space between the second main segments 21, and may be diffracted by a grating structure.

The light I incident on the second main pattern 20 may be divided into the zero-order diffraction beam I0 and the first-order diffraction beam I1 by diffraction. The first-order diffraction beams I1 may be detected at positions opposite to each other with respect to the zero-order diffraction beam I0. That is, the first-order diffraction beams I1 may be directed in +X direction and −X direction that are opposite to each other with respect to the zero-order diffraction beam I0.

In the case of scanning along the first direction X, an effective signal may be generated by the second main pattern 20. On the other hand, when scanning along the first direction X, noise may occur in the first main pattern 10 extending parallel to the first direction X that is the scan direction.

The second main pattern 20 may have a line and space structure. A width a2 of the second main segment 21 of the second main pattern 20 corresponding to the line, and a distance b2 between the second main segments 21 corresponding to the space may affect the angles of diffraction beam together. The width a2 of the line and a width b2 of the space may be changed according to the position of the alignment sensor for detecting the diffraction beam.

Referring to FIG. 10, the alignment marks AM_X and AM_Y may be scanned along the second direction Y. If light moves along the second direction Y, diffraction may occur in the first main pattern 10 extending in the first direction X perpendicular to the second direction Y. The light I may be incident on the space between the first main segments 11 and may be diffracted by a grating structure.

The light I incident on the first main pattern 10 may be divided into the zero-order diffraction beam I0 and the first-order diffraction beam I1 by diffraction. The first-order diffraction beam I1 may be detected at positions opposite to each other with respect to the zero-order diffraction beam I0. That is, the first-order diffraction beams I1 may be directed in the +Y direction and the −Y direction that are opposite to each other with respect to the zero-order diffraction beam I0.

In the case of scanning along the second direction Y, an effective signal may be generated by the first main pattern 10. On the other hand, when scanning along the second direction Y, noise may occur in the second main pattern 20 extending parallel to the second direction Y that is the scan direction.

The first main pattern 10 may have a line and space structure. A width a1 of the first main segment 11 of the first main pattern 10 corresponding to the line, and a distance b1 between the first main segments 21 corresponding to the space may affect the angle of diffraction beam, the intensity of diffraction beam, the contrast, etc. together. The width a1 of the line and the width b1 of the space may be changed according to the position of the alignment sensor for detecting the diffraction beam.

FIG. 11 is a graph illustrating a signal generated by detecting diffraction beam generated while a scan area moves. The X-axis may represent the position of the scan area and the Y-axis may represent the intensity of the signal. The signal obtained by summing the acquired signals in the same phase is illustrated as Iₛᵤₘ, and the signal obtained by summing the acquired signals in opposite phases is illustrated as I_{diff}.

The area where both Iₛᵤₘ and I_{diff} appear may be referred to as the effective signal range. In the graph of FIG. 11, the effective signal range may correspond to all positions where the scan area moves. Therefore, it may be interpreted that an effective signal is generated in all sections in which the scan area moves. The area where the effective signal is generated is ensured, and optical performance (e.g., contrast) can be improved.

Meanwhile, deformation may occur in the alignment mark in the semiconductor manufacturing process. Deformation such as abrasion or peeling of a part of the first main segment and/or a part of the second main segment of the alignment mark may occur. If deformation occurs in the first main segment and/or the second main segment, the width of the line and the width of the space changes so that the angle of the diffraction beam is changed, and the intensity, contrast, etc. of the diffraction beam may be lowered. For the alignment mark according to some example embodiments, because the effective signal area is secured, even if deformation occurs in the first main segment and/or the second main segment, the alignment of the wafers may be stably performed. As described above, with the structure of the alignment mark, the substrate structure according to some aspects may more precisely align wafers.

Although it is illustrated that the first main pattern 10 and the second main pattern 20 are disposed on different layers, in some example embodiments, the first main pattern 10 and the second main pattern 20 may be disposed on the same layer to generate the diffraction effect described above.

Hereinafter, alignment marks according to another example embodiment will be described. The same reference numerals are used for the same components as in the above-described examples, and detailed description thereof may be omitted.

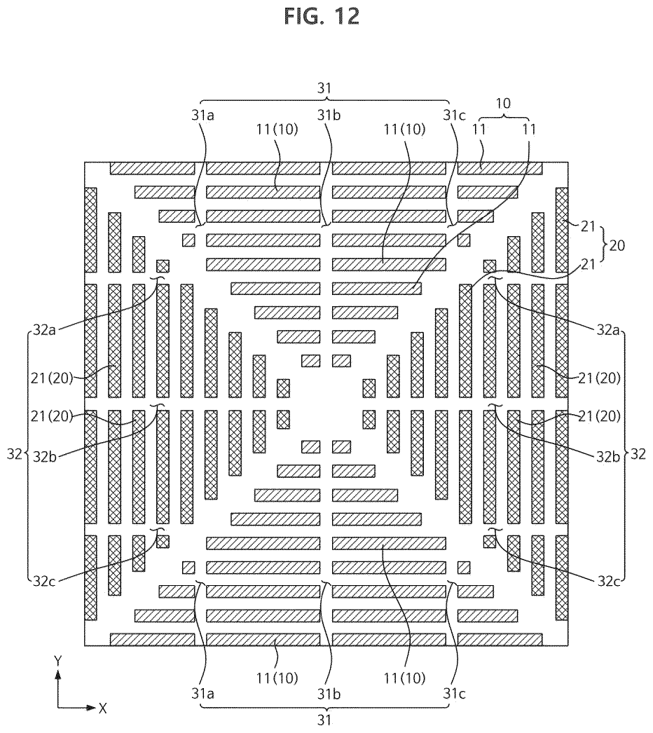

FIGS. 12 to 19 are diagrams illustrating alignment marks according to some example embodiments.

Referring to FIG. 12, a plurality of first separation grooves 31 and a plurality of second separation grooves 32 may be provided. The plurality of first separation grooves 31a, 31b, and 31c may separate the first main pattern 10 in the first direction X. The plurality of first separation grooves 31a, 31b, and 31c may be spaced apart from each other in the first direction X. Each of the plurality of first separation grooves 31a, 31b, and 31c may extend in the second direction Y. The plurality of second separation grooves 32a, 32b, and 32c may separate the second main pattern 20 in the second direction Y. The plurality of second separation grooves 32a, 32b, and 32c may be spaced apart from each other in the second direction Y. Each of the plurality of second separation grooves 32a, 32b, and 32c may extend in the first direction X.

Due to the presence of the plurality of first separation grooves 31 and the plurality of second separation grooves 32, foreign substances remaining in the first main pattern 10 and the second main pattern 20 may be more easily discharged.

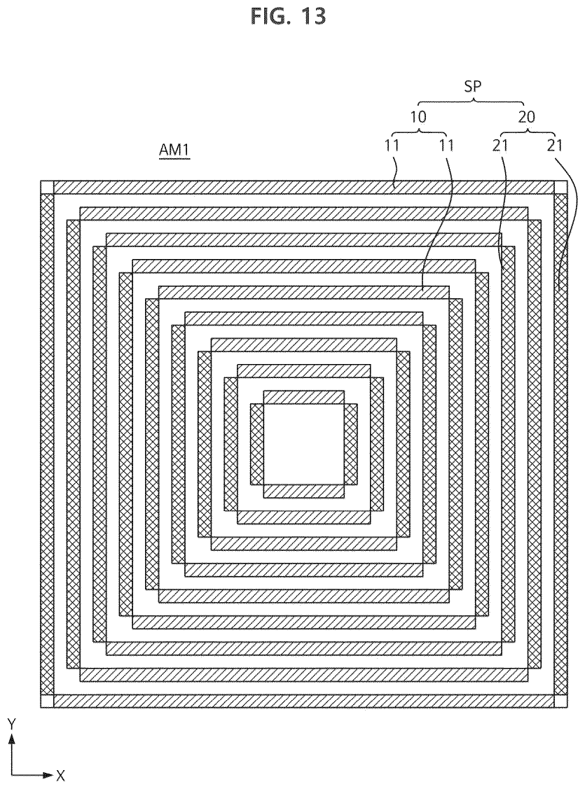

Referring to FIG. 13, an alignment mark AM1 may include the first main pattern 10 in which the first main segment 11 is repeatedly formed, and the second main pattern 20 in which the second main segment 21 is repeatedly formed. The first main pattern 10 and the second main pattern 20 may form a quadrangle pattern. For example, when viewed in a plan view, the first main pattern 10 and the second main pattern 20 may form a square pattern SP.

The first main segment 11 and the second main segment 21 may form a square pattern SP. The square pattern SP may form a part of each square excluding the corner portions. When viewed in a plan view, the first main segment 11 and the second main segment 21 may be in point contact at the corner portion of the square. The inside surrounded by the first main segment 11 and the second main segment 21 may be closed. The first main segment 11 and the second main segment 21 may be formed on layers of different levels, respectively. When viewed in a plan view, the first main segment 11 and the second main segment 21 may not overlap each other.

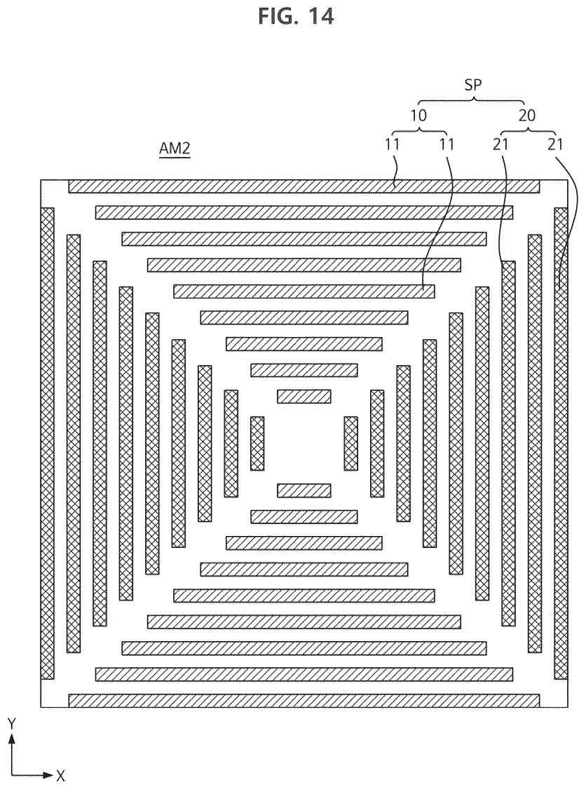

Referring to FIG. 14, an alignment mark AM2 may include the first main pattern 10 in which the first main segment 11 is repeatedly formed, and the second main pattern 20 in which the second main segment 21 is repeatedly formed. The first main pattern 10 and the second main pattern 20 may form a quadrangle pattern. For example, when viewed in a plan view, the first main pattern 10 and the second main pattern 20 may form a square pattern SP.

The first main segment 11 and the second main segment 21 may form a square pattern SP. The square pattern SP may form a part of each square. The first main segment 11 and the second main segment 21 may be formed on layers of different levels, respectively. When viewed in a plan view, the first main segment 11 and the second main segment 21 may not overlap each other. The continuous groove of the alignment mark AM2 formed in diagonal direction to form an X shape may perform a function similar to the separation groove described above.

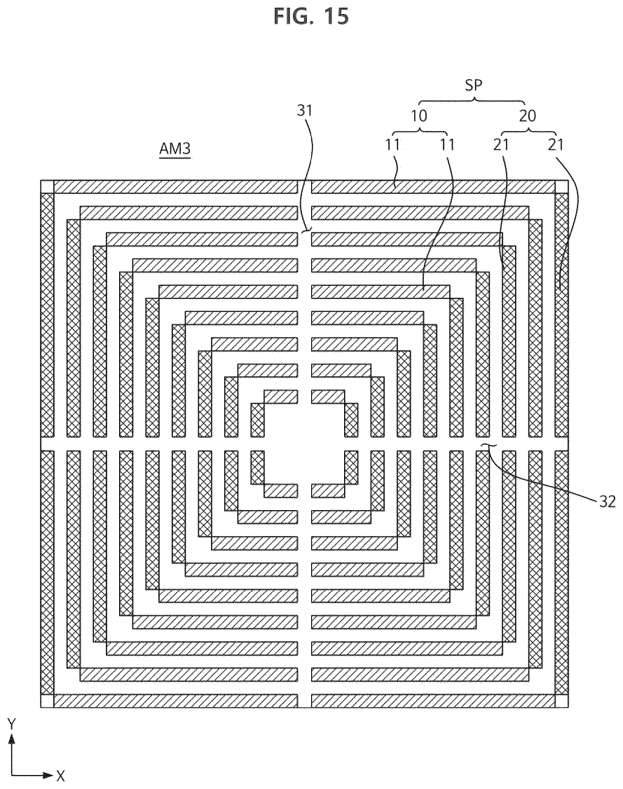

Referring to FIG. 15, an alignment mark AM3 may include the first main pattern 10 in which the first main segment 11 is repeatedly formed, and the second main pattern 20 in which the second main segment 21 is repeatedly formed. The first main pattern 10 and the second main pattern 20 may form a quadrangle pattern. The first main segment 11 and the second main segment 21 may be formed on layers of different levels, respectively. For example, when viewed in a plan view, the first main pattern 10 and the second main pattern 20 may form a square pattern SP.

The first main segment 11 and the second main segment 21 may form a square pattern SP. The square pattern SP may form a part of each square excluding the corner portions. When viewed in a plan view, the first main segment 11 and the second main segment 21 may be in point contact at the corner portion of the square. The inside surrounded by the first main segment 11 and the second main segment 21 may be closed. Meanwhile, when viewed in a plan view, the first main segment 11 and the second main segment 21 may not overlap each other.

The alignment mark AM3 may include the first separation groove 31 for separating the first main patterns 10 in the first direction X and the second separation groove 32 for separating the second main patterns 20 in the second direction Y. The first separation groove 31 may extend in the second direction Y, and the second separation groove 32 may extend in the first direction X. In some example embodiments, a plurality of first separation grooves 31 and a plurality of second separation grooves 32 may be provided.

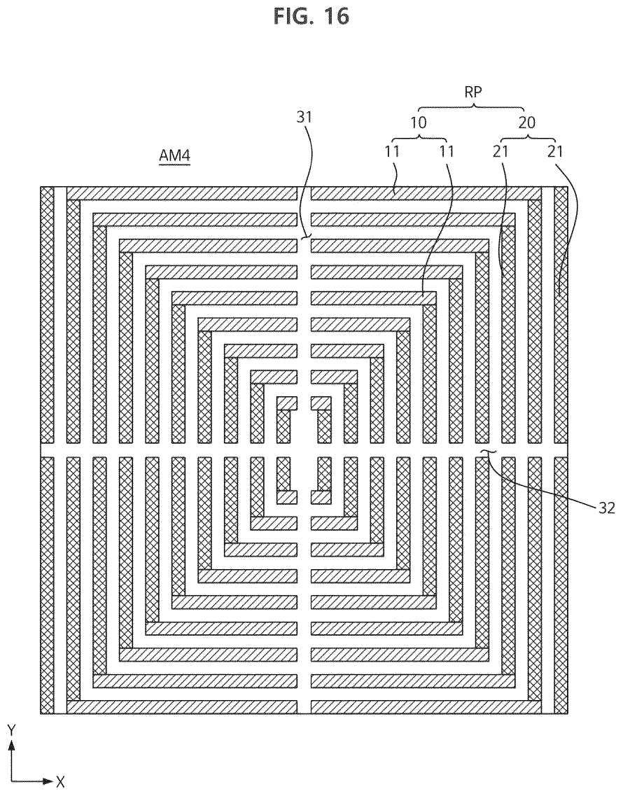

Referring to FIG. 16, an alignment mark AM4 may include the first main pattern 10 in which the first main segment 11 is repeatedly formed, and the second main pattern 20 in which the second main segment 21 is repeatedly formed. The first main pattern 10 and the second main pattern 20 may form a quadrangle pattern. For example, when viewed in a plan view, the first main pattern 10 and the second main pattern 20 may form a rectangular pattern RP.

The first main segment 11 and the second main segment 21 may form a rectangular pattern RP. The first main segment 11 and the second main segment 21 may form four sides of each rectangle of the rectangular pattern RP. The first main segment 11 may form a short side of each rectangle of the rectangular pattern RP. The second main segment 21 may form a long side of each rectangle of the rectangular pattern RP. The first main segment 11 and the second main segment 21 may be formed on layers of different levels, respectively. When viewed in a plan view, the first main segment 11 and the second main segment 21 may not overlap each other.

The center of the rectangular pattern RP may coincide with the center of the alignment mark AM4. The center of each rectangle configuring the rectangular pattern RP may share the center with the alignment mark AM4. The center of the rectangle may be an intersection point of diagonal lines of the rectangle.

The alignment mark AM4 may include the first separation groove 31 for separating the first main patterns 10 in the first direction X and the second separation groove 32 for separating the second main patterns 20 in the second direction Y. The first separation groove 31 may extend in the second direction Y, and the second separation groove 32 may extend in the first direction X. In some example embodiments, a plurality of first separation grooves 31 and a plurality of second separation grooves 32 may be provided.

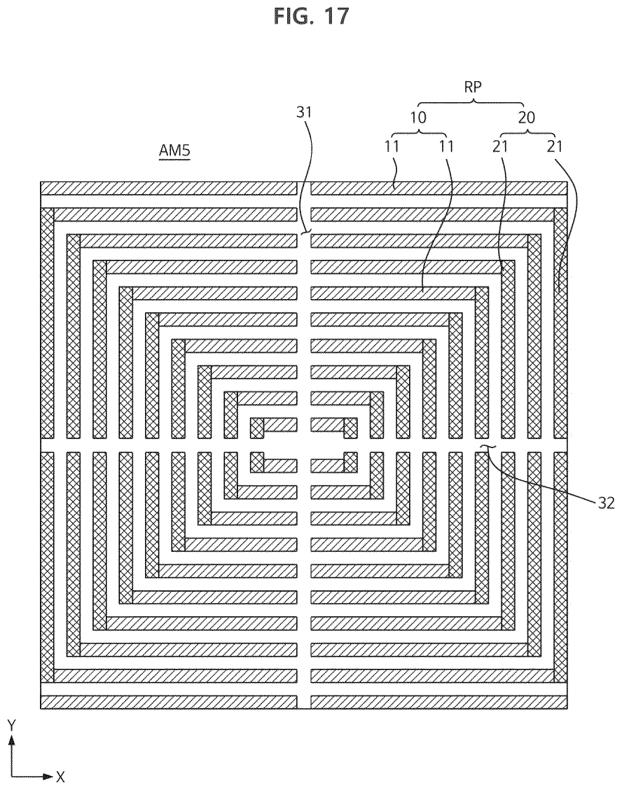

Referring to FIG. 17, an alignment mark AM5 may include the first main pattern 10 in which the first main segment 11 is repeatedly formed, and the second main pattern 20 in which the second main segment 21 is repeatedly formed. The first main pattern 10 and the second main pattern 20 may form a quadrangle pattern. For example, when viewed in a plan view, the first main pattern 10 and the second main pattern 20 may form a rectangular pattern RP.

The first main segment 11 and the second main segment 21 may form a rectangular pattern RP. The first main segment 11 and the second main segment 21 may form four sides of each rectangle of the rectangular pattern RP. The first main segment 11 may form a long side of each rectangle of the rectangular pattern RP. The second main segment 21 may form a short side of each rectangle of the rectangular pattern RP. The first main segment 11 and the second main segment 21 may be formed on layers of different levels, respectively. When viewed in a plan view, the first main segment 11 and the second main segment 21 may not overlap each other.

The center of the rectangular pattern RP may coincide with the center of the alignment mark AM5. The center of each rectangle configuring the rectangular pattern RP may share the center with the alignment mark AM5. The center of the rectangle may be an intersection point of diagonal lines of the rectangle.

The alignment mark AM4 may include the first separation groove 31 for separating the first main patterns 10 in the first direction X and the second separation groove 32 for separating the second main patterns 20 in the second direction Y. The first separation groove 31 may extend in the second direction Y, and the second separation groove 32 may extend in the first direction X. In some example embodiments, a plurality of first separation grooves 31 and a plurality of second separation grooves 32 may be provided.

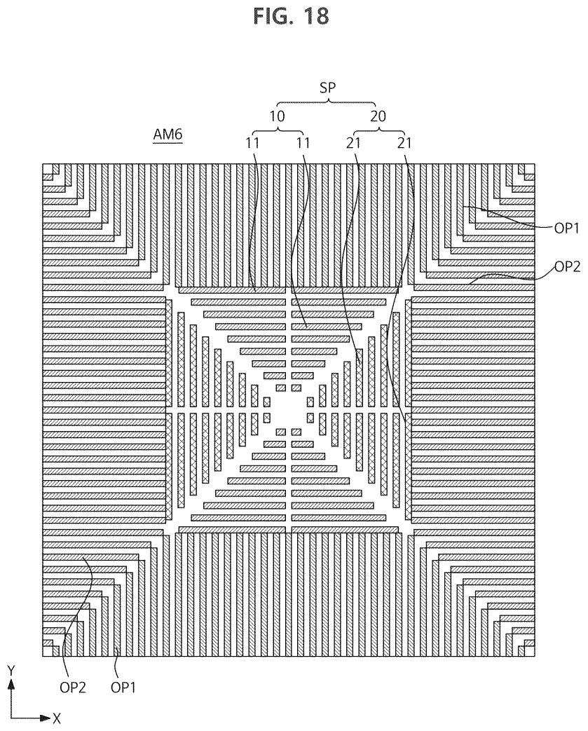

Referring to FIG. 18, an alignment mark AM6 may include a quadrangle pattern therein. The quadrangle pattern may be a square pattern SP. However, example embodiments are not limited thereto, and the quadrangle pattern may be a rectangular pattern.

The alignment mark AM6 may include, outside the square pattern SP, a first outer pattern OP1 perpendicular to the first main pattern 10 and a second outer pattern OP2 perpendicular to the second main pattern 20. The first outer pattern OP1 may extend in a second direction Y perpendicular to the first direction X, which is the extending direction of the first main pattern 10. The second outer pattern OP2 may extend in the first direction X perpendicular to the second direction Y which is the extending direction of the second main pattern 20.

In some example embodiments, patterns having various structures may be formed outside the square pattern SP. Any pattern may be formed outside the square pattern SP as long as the square pattern SP is included.

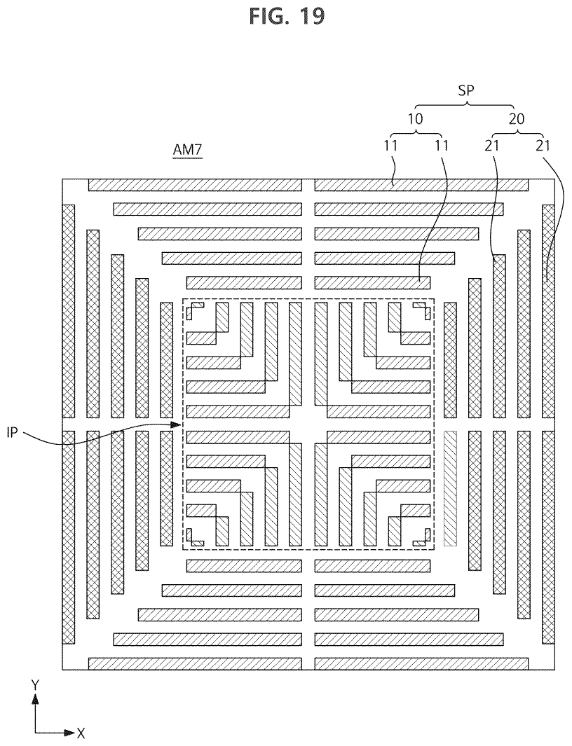

Referring to FIG. 19, an alignment mark AM7 may include a quadrangle pattern formed outside. The quadrangle pattern may be a square pattern SP. However, example embodiments are not limited thereto, and the quadrangle pattern may be a rectangular pattern.

An inner pattern IP in which segments extending in the first direction X and segments extending in the second direction Y are repeated may be disposed inside the square pattern SP. In addition, the segments of the inner pattern IP may be symmetrically disposed based on the first direction X or the second direction Y, respectively. In addition, the segments may form an individual quadrangle pattern, respectively.

In some example embodiments, patterns having various structures may be formed inside the square pattern SP. Any pattern may be formed inside the square pattern SP as long as the square pattern SP is included.

Although some example embodiments have been described in this specification and drawings, the present disclosure is not limited to the disclosed example embodiments. It goes without saying that various changes and modifications can be made within the equivalent scope of the inventive concepts of the present disclosure and the claims to be described below by those of ordinary skill in the art.

What is claimed is:

1. A substrate structure, comprising:
a substrate; and
an alignment mark on the substrate and configured to align the substrate,
wherein the alignment mark includes
a first main pattern in which a first main segment extending in a first direction repeats in a second direction perpendicular to the first direction, and
a second main pattern in which a second main segment extending in the second direction repeats in the first direction,
wherein the first main pattern and the second main pattern define a quadrangle pattern in a plan view, and
wherein the first main pattern and the second main pattern are configured to diffract a light incident on the alignment mark.

2. The substrate structure according to claim 1, wherein
the first main pattern includes a first sub-pattern, the first sub-pattern repeating along the first direction on the first main segment, and
the second main pattern includes a second sub-pattern, the second sub-pattern repeating along the second direction on the second main segment.

3. The substrate structure according to claim 1, wherein
the first main pattern is symmetric with respect to a first symmetry axis extending along the first direction and passing through a center of the alignment mark, and
the second main pattern is symmetric with respect to a second symmetry axis extending along the second direction and passing through the center of the alignment mark.

4. The substrate structure according to claim 1, wherein a length of the first main segment in the first direction increases along the second direction from a center of the alignment mark toward an edge of the alignment mark.

5. The substrate structure according to claim 4, wherein a length of the second main segment in the second direction increases along the first direction from the center of the alignment mark toward the edge of the alignment mark.

6. The substrate structure according to claim 1, wherein the alignment mark further includes:
a first separation groove extending in the second direction and configured to separate the first main pattern in the first direction; and
a second separation groove extending in the first direction and configured to separate the second main pattern in the second direction.

7. The substrate structure according to claim 6, wherein
the first separation groove includes a plurality of first separation grooves,
the second separation groove includes a plurality of second separation grooves,
the plurality of first separation grooves are spaced apart from each other in the first direction, and
the plurality of second separation grooves are spaced apart from each other in the second direction.

8. The substrate structure according to claim 1, further comprising:
a first layer; and
a second layer at a different level from the first layer,
wherein the first main pattern is on the first layer, and the second main pattern is on the second layer.

9. The substrate structure according to claim 8, wherein the second layer is positioned at a higher level than the first layer.

10. The substrate structure according to claim 1, wherein the first main pattern and the second main pattern do not to overlap each other along a thickness direction of the substrate.

11. The substrate structure according to claim 1, wherein the alignment mark further includes:
a first outer pattern outside the quadrangle pattern and perpendicular to the first main pattern; and
a second outer pattern outside the quadrangle pattern and perpendicular to the second main pattern.

12. The substrate structure according to claim 1, wherein the alignment mark further includes an inner pattern inside the quadrangle pattern.

13. A substrate structure, comprising:
a substrate comprising a chip area and a scribe lane surrounding the chip area; and
an alignment mark on the scribe lane and configured to diffract incident light,
wherein the alignment mark includes
a first main pattern in which a first main segment extending in a first direction repeats in a second direction perpendicular to the first direction,
a second main pattern in which a second main segment extending in the second direction repeats in the first direction,
a first sub-pattern including a first sub-segment and the first sub-segment repeating along the first direction on the first main segment, and
a second sub-pattern including a second sub-segment, the second sub-segment repeating along the second direction on the second main segment,
wherein a length of the first main segment in the first direction increases from a center of the alignment mark toward an edge of the alignment mark, and
wherein a length of the second main segment in the second direction increases from the center of the alignment mark toward the edge of the alignment mark.

14. The substrate structure according to claim 13, wherein
the substrate includes a first layer and a second layer, the first layer and the second layer being disposed at different levels from each other, and
the first main pattern is on the first layer, and the second main pattern is on the second layer.

15. The substrate structure according to claim 14, wherein the alignment mark further includes:
a first separation groove extending in the second direction and configured to separate the first main pattern in the first direction; and
a second separation groove extending in the first direction and configured to separate the second main pattern in the second direction.

16. The substrate structure according to claim 13, wherein
the first main pattern is symmetric with respect to a first straight line, the first straight line extending along the first direction and passing through the center of the alignment mark, and
the second main pattern is symmetric with respect to a second straight line, the second straight line extending along the second direction and passing through the center of the alignment mark.

17. The substrate structure according to claim 13, wherein, in a plan view, the first main segment and the second main segment define a quadrangle pattern having a same center as the center of the alignment mark as a same center.

18. The substrate structure according to claim 17, wherein the quadrangle pattern includes a square pattern.

19. The substrate structure according to claim 13, wherein
a width of the first main segment in the second direction and a pitch of the first main segment in the second direction are same as each other, and
a width of the second main segment in the first direction and a pitch of the second main segment in the first direction are same as each other.

20. A substrate structure, comprising:
a substrate; and
an alignment mark on the substrate,
wherein the alignment mark includes
a base,
a first main pattern in which a first main segment protruding from the base and extending in a first direction repeats in a second direction perpendicular to the first direction,
a second main pattern in which a second main segment protruding from the base and extending in the second direction repeats in the first direction,
a first sub-pattern including a first sub-segment, the first sub-segment repeating along the first direction on the first main segment,
a second sub-pattern including a second sub-segment, the second sub-segment repeating along the second direction on the second main segment,
a first separation groove extending in the second direction and configured to separate the first main pattern in the first direction, and
a second separation groove extending in the first direction and configured to separate the second main pattern in the second direction,
wherein a length of the first main segment in the first direction increases from a center of the alignment mark toward an edge of the alignment mark,
wherein a length of the second main segment in the second direction increases from the center of the alignment mark toward the edge of the alignment mark, and
wherein when viewed in a plan view, the first main pattern and the second main pattern define a quadrangle pattern having a same center as the center of the alignment mark.
